(19) United States
(12) Patent Application Publication
(10) Pub. No.: US 2009/0272980 A1
(43) Pub. Date: Nov. 5, 2009

(54) THIN FILM TRANSISTOR ARRAY PANEL AND MANUFACTURING METHOD OF THE SAME

(76) Inventors: Seung-Hwan SHIM, Seongnam-si (KR); Ki-Hun JEONG, Seoul (KR); Joo-Han KIM, Yongin-si (KR); Sung-Hoon YANG, Seoul (KR); Hong-kee CHIN, Suwon-si (KR)

Correspondence Address: Haynes and Boone, LLP;IP Section, 2323 Victory Avenue, SUITE 700, Dallas, TX, 75219, US

(21) Appl. No.: 12/272,624

(22) Filed: Nov. 17, 2008

(30) Foreign Application Priority Data
May 2, 2008 (KR) 10-2008-0041320

(51) Int. Cl. H01L 31/036; H01L 21/84

(52) U.S. Cl. 257/72; 438/158; 257/E33.053

(57) ABSTRACT

A semiconductor including a channel, a data line including a source electrode, a drain electrode, and a pixel area definition member is formed on a gate insulating layer, and a passivation layer is deposited on the data line, the pixel area definition member, and the channel of the semiconductor. A first photosensitive film pattern including a first portion disposed at a position corresponding to the drain electrode and a second portion that is thicker than the first portion, and exposing the passivation layer at a position corresponding to the pixel area definition member, is formed on the passivation layer, the passivation layer that is exposed by using the first photosensitive film pattern as an etch mask is etched, and a second photosensitive film pattern is formed by etching the whole surface of the first photosensitive film pattern to remove the first portion. The pixel area definition member exposed by the passivation layer is etched, and the passivation layer exposed by the removal of the first portion and the semiconductor exposed by the removal of the pixel area definition member are etched. A conductor layer for a pixel electrode is formed, and the second photosensitive film pattern is removed to form the pixel electrode.

### CROSS-REFERENCE TO RELATED APPLICATION

This application claims priority to and the benefit of Korean Patent Application No. 10-2008-0041320 filed in the Korean Intellectual Property Office on May 2, 2008, the entire contents of which are incorporated herein by reference.

### BACKGROUND OF THE INVENTION

(a) Field of the Invention

The present invention relates to a thin film transistor array panel and a manufacturing method thereof.

(b) Description of the Related Art

In a flat panel display such as a liquid crystal display (LCD) or an organic light emitting diode (OLED) display, a thin film transistor (TFT) is generally used as a switching element for independently driving each pixel. A thin film transistor array panel including the thin film transistor includes a scanning signal line (gate line) for transmitting a scanning signal to the thin film transistor and a data line for transmitting a data signal, as well the thin film transistor and a pixel electrode connected thereto.

To form the thin film transistor array panel, several photolithography processes are required, and one photolithography process includes detailed processes of several tens to hundreds of steps such that if the number of photolithography processes is increased, the process time and manufacturing costs are increased. Accordingly, various methods to reduce the number of photolithography processes have been proposed. However there are problems involved with reducing the number of photolithography processes such that it is not easy to reduce the number of photolithography processes and masks.

### SUMMARY OF THE INVENTION

The present invention reduces the number of photolithography processes for a manufacturing method of a thin film transistor array panel without any accompanying problems.

A thin film transistor array panel according to an exemplary embodiment of the present invention includes: a substrate; a gate line formed on the substrate and including a gate electrode; a gate insulating layer formed on the gate line; a semiconductor formed on the gate insulating layer and including a channel of a thin film transistor; a data line formed on the semiconductor and including a source electrode; a drain electrode formed on the semiconductor and facing the source electrode with respect to the channel of the thin film transistor; a passivation layer covering the data line and the gate line, and having a first opening exposing the gate insulating layer of the pixel area enclosed by the data line and the gate line, and a portion of the drain electrode; and a pixel electrode formed on the gate insulating layer in the first opening and connected to the drain electrode.

The plane shape of the pixel electrode may be substantially the same as the plane shape of the first opening, an edge member including a first layer made of the same material as the semiconductor and a second layer made of the same material as the data line and the edge member being formed along the edge of the pixel electrode may be further included, and the edge of the pixel electrode covers one side and the upper surface of the edge member.

A storage electrode line formed of the same layer as the gate line and including a plurality of storage electrodes extending along the data line may be further included, the width of the storage electrode is wider than the width of the data line, and the data line may be disposed inside the width of the storage electrode.

The passivation layer and the gate insulating layer include a second opening exposing an end portion of the gate line and the passivation layer may have a third opening exposing an end portion of the data line, a first contact assistant covering the end portion of the gate line exposed through the second opening and a second contact assistant covering the end portion of the data line exposed through the third opening may be further included, and the plane shape of the first contact assistant may be substantially the same as the second opening and the plane shape of the second contact assistant is substantially the same as the plane shape of the third opening. The first contact assistant may contact the substrate near the end portion of the gate line, and the second contact assistant may contact the gate insulating layers near the end portion of the data line.

A manufacturing method of thin film transistor array panel according to an exemplary embodiment of the present invention includes: forming a gate line including a gate electrode; forming a gate insulating layer on the gate line; forming a semiconductor including a channel, a data line including a source electrode, a drain electrode, and a pixel area definition member on the gate insulating layer; depositing a passivation layer on the data line, the pixel area definition member, and the channel of the semiconductor; forming a first photosensitive film pattern including a first portion disposed at a position corresponding to the drain electrode and a second portion that is thicker than the first portion, and exposing the passivation layer of the position corresponding to the pixel area definition member on the passivation layer; etching the exposed passivation layer by using the first photosensitive film pattern as an etch mask; forming a second photosensitive film pattern by etching the whole surface of the first photosensitive film pattern to remove the first portion; etching the pixel area definition member exposed by the etching of the passivation layer; etching the passivation layer that is exposed by the removal of the first portion, and the semiconductor that is exposed by the removal of the pixel area definition member; forming a conductor layer for a pixel electrode; and removing the second photosensitive film pattern to form the pixel electrode.

The first photosensitive film pattern may expose a portion of the passivation layer corresponding to the end portion of the gate line, and may include a third portion disposed at a position corresponding to the end portion of the data line and being thinner than the second portion; the portion of the passivation layer corresponding to the end portion of the gate line may be removed in the etching of the exposed passivation layer by using the first photosensitive film pattern as an etch mask; the third portion may be removed in the forming of a second photosensitive film pattern by etching the whole surface of the first photosensitive film pattern to remove the first portion; and a portion of the passivation layer which is exposed by the removal of the third portion may be removed to expose the end portion of the data line in the etching of the passivation layer that is exposed by the removal of the first portion, and the semiconductor that is exposed by the removal of the pixel area definition member.

A first contact assistant covering the end portion of the gate line and a second contact assistant covering the end portion of the data line may be formed in the removing of the second photosensitive film pattern to form the pixel electrode.

The forming a semiconductor including a channel, a data line including a source electrode, a drain electrode, and a pixel area definition member on the gate insulating layer may include: continuously depositing an amorphous silicon layer, a doped amorphous silicon layer, and a data metal layer on the gate insulating layer; forming a third photosensitive film pattern including a fourth portion disposed at a position corresponding to the channel, and a fifth portion that is thicker than the fourth portion and is disposed at a position corresponding to the data line, the drain electrode, and the pixel area definition member on the data metal layer; etching the data metal layer, the doped amorphous silicon layer, and the amorphous silicon layer by using the third photosensitive film pattern as a mask; etching the whole surface of the third photosensitive film pattern to remove the fourth portion and form a fourth photosensitive film pattern; and etching the data metal layer and the doped amorphous silicon layer by using the fourth photosensitive film pattern as a mask.

The etching of the passivation layer that is exposed by the removal of the first portion, and the semiconductor that is exposed by the removal of the pixel area definition member may include a first etching executed under a condition in which an etch selectivity for the semiconductor and the passivation layer is 1:1, and a second etching executed under a condition in which an etch selectivity for the semiconductor and the passivation layer is 1:5.

The semiconductor may be left with a thickness of 400-600 Å in the first etching, and the passivation layer may be over-etched to form an under-cut under the second photosensitive film pattern in the second etching.

A storage electrode line including a plurality of storage electrodes extending along the data line may be formed in the forming a gate line including a gate electrode.

According to an exemplary embodiment of the present invention, the metal layer and the semiconductor layer are left in the region in which the pixel electrode will be formed when forming the data wire such that the pixel electrode may be formed on the gate insulating layer on the final structure. Accordingly, the number of steps is reduced in the pixel area, while reducing the light leakage and preventing an interlayer short that is easily generated in the absence of the gate insulating layer.

### BRIEF DESCRIPTION OF THE DRAWINGS

FIG. 1 is a layout view of a thin film transistor array panel according to an exemplary embodiment of the present invention.

FIG. 2 is a cross-sectional view of the thin film transistor array panel shown in FIG. 1 taken along the line II-II.

FIG. 3 is a cross-sectional view of the thin film transistor array panel shown in FIG. 1 taken along the lines III-III′ and III-III″.

FIG. 6 and FIG. 11 are layout views showing intermediate steps of a manufacturing process of the thin film transistor array panel according to an exemplary embodiment of the present invention.

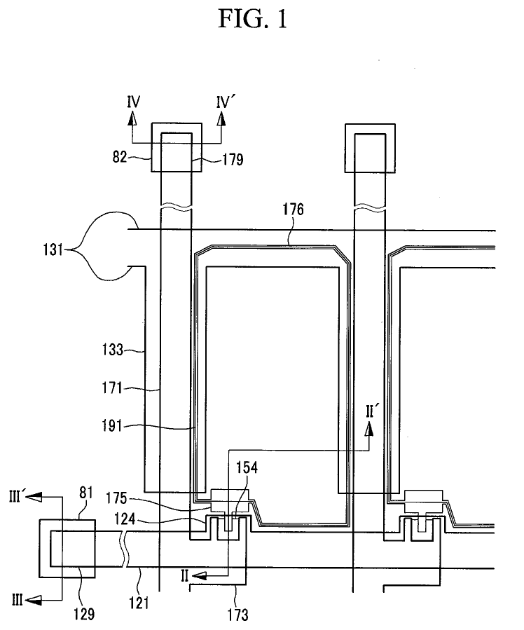

FIG. 4, FIG. 7, FIG. 9, FIG. 12, FIG. 14, FIG. 16, and FIG. 18 are cross-sectional views showing intermediate steps of a manufacturing process of the thin film transistor array panel according to an exemplary embodiment of the present invention and taken along the line II-II′ of FIG. 1.

FIG. 5, FIG. 8, FIG. 10, FIG. 13, FIG. 15, FIG. 17, and FIG. 19 are cross-sectional views showing intermediate steps of a manufacturing process of the thin film transistor array panel according to an exemplary embodiment of the present invention and taken along the lines III-III′ and III′-III″ of FIG. 1.

### DETAILED DESCRIPTION OF THE EMBODIMENTS

The present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

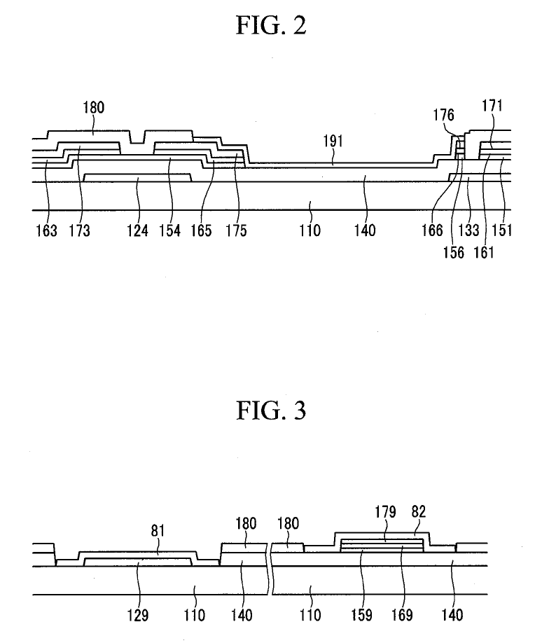

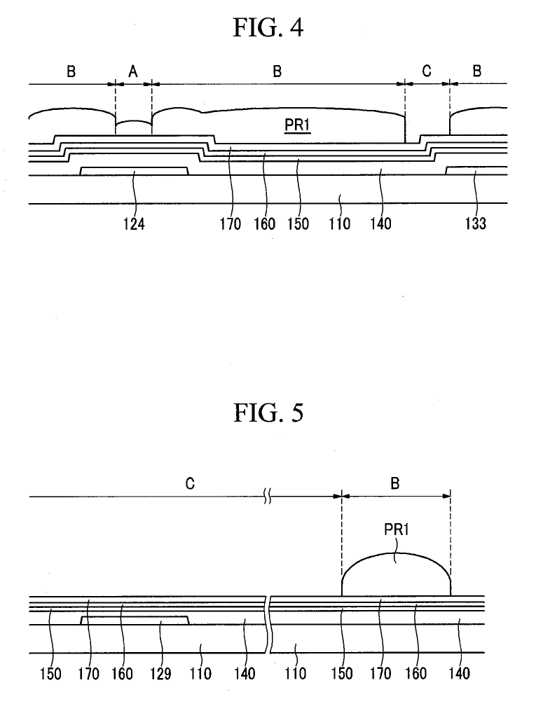

Now, a thin film transistor array panel according to an exemplary embodiment of the present invention will be described in detail with reference to FIG. 1, FIG. 2 and FIG. 3.

FIG. 1 is a layout view of a thin film transistor array panel according to an exemplary embodiment of the present invention, FIG. 2 is a cross-sectional view of the thin film transistor array panel shown in FIG. 1 taken along the line II-II′, and FIG. 3 is a cross-sectional view of the thin film transistor array panel shown in FIG. 1 taken along the line III-III′ and IV-IV′.

With reference to FIG. 1 and FIG. 2, a plurality of gate lines 121 for transmitting gate signals and storage electrode lines 131 are formed on an insulation substrate 110 made of a material such as a transparent glass. Each gate line 121 extends in a transverse direction with respect to FIG. 1 and includes a plurality of gate electrodes 124 and an end portion 129. The storage electrode lines 131 extend in a transverse direction and include a plurality of storage electrodes 133 extending in a longitudinal direction with respect to FIG. 1.

With reference to FIG. 2 and FIG. 3, a gate insulating layer 140 is formed on the gate lines 121.

A plurality of intrinsic semiconductors 154 preferably made of amorphous silicon is formed on the gate insulating layer 140.

A plurality of ohmic contacts 161, 163, 165, 166, and 169 preferably made of a material such as n+hydrogenated amorphous silicon into which an n-type impurity is doped at a high concentration, or of silicide, is formed on intrinsic semiconductors 151, 154, 156, and 159. For convenience, the intrinsic semiconductors 151, 154, 156, and 159 and the ohmic contacts 161, 163, 165, 166, and 169 may be commonly referred to as semiconductors, and the term “semiconductor” may mean a polysilicon semiconductor or an oxide semiconductor as well as an intrinsic semiconductor and an ohmic contact layer.

A plurality of data lines 171, a plurality of drain electrodes 175, and a plurality of edge metal layers 176 are formed on the ohmic contacts 161, 163, 165, 166, and 169.

The data lines 171 extend in the longitudinal direction, thereby intersecting the gate lines 121, and transmit data voltages. Each data line 171 includes a plurality of source electrodes 173, and the drain electrodes 175 are disposed opposite to the source electrodes 173 with respect to the gate electrodes 124.

The edge metal layers 176 are formed in a shape that encloses most regions in the pixel area enclosed by the gate lines 121 and the data lines 171, and form an enclosed curved line with the drain electrodes 175.

The ohmic contacts 161, 163, 165, 166, and 169 and the intrinsic semiconductors 151, 154, 156, and 159 exist under the data lines 171, the drain electrodes 175, and the edge metal layers 176, and the channel of the intrinsic semiconductors 154 between the source electrode 173 and the drain electrode 175 is exposed. Here, the edge metal layers 176, the underlying ohmic contacts 166, and the intrinsic semiconductor 156 may be omitted.

A gate electrode 124, a source electrode 173, and a drain electrode 175 form a thin film transistor along with an intrinsic semiconductor 154, and the channel of the thin film transistor is formed in the channel portion of the intrinsic semiconductor 154 between the source electrode 173 and the drain electrode 175.

A passivation layer 180 is formed on the gate insulating layer 140, the data lines 171, the drain electrodes 175, and the channel portion of the intrinsic semiconductor 154. The passivation layer 180 is made of an inorganic insulating material such as silicon nitride or silicon oxide, or an organic insulating material such as a resin.

The passivation layer 180 has a plurality of first openings exposing portions of the drain electrode 175 and the pixel areas enclosed by the gate lines 121 and the data lines 171 and a plurality of third openings exposing end portions 179 of the data lines 171, and the passivation layer 180 and the gate insulating layer 140 have a plurality of second openings exposing the end portions 129 of the gate lines 121. The third openings may expose the gate insulating layer 140 near the end portions 179 of the data lines 171, and the second openings may expose the substrate 110 near the end portions 129 of the gate lines 121. When forming the edge metal layers 176, the edge metal layers 176 are disposed along the boundary of the first openings. The reason for this is that the edge metal layer 176, the underlying ohmic contacts 166, and the intrinsic semiconductor 156 limit the etching progress of the passivation layer 180, thereby confirming the boundary of the first openings in the manufacturing process.

A plurality of pixel electrodes 191 are formed on the drain electrodes 175 and the gate insulating layer 140 in the first openings, a plurality of first contact assistants 81 are formed on the end portions 129 of the gate lines 121 and the substrate 110 in a region near the second openings, and a plurality of second contact assistants 82 are formed on the end portions 179 of the data lines 171 and the gate insulating layer 140 in a region near in the third openings. The shape of the pixel electrodes 191 in plan view is substantially equal to the shape of the first openings and the shape of the first contact assistants 81 and the second contact assistants 82 are substantially equal to the shape of the second openings and the third openings, respectively in plan view. This is because the pixel electrodes 191, the first contact assistants 81, and the second contact assistants 82 are formed by a lift-off method using the photosensitive film pattern when forming the passivation layer 180. Also, the pixel electrodes 191 may totally or partially cover one side and the upper surface of the edge metal layer 176.

The pixel electrodes 191 receive data voltages from the drain electrodes 175.

The contact assistants 81 and 82 respectively cover the end portions 129 and 179 of the gate lines 121 and data lines 171. The contact assistants 81 and 82 complement adhesion of the end portion 129 of the gate line 121 and the end portion 179 of the data line 171 with external devices such as a driver IC, and protect the end portion 129 of the gate line 121 and the end portion 179 of the data line 171.

In the thin film transistor, the gate insulating layer 140 is not removed and remains in the pixel area, and the steps between the portions where the passivation layer remains and does not remain are small. Accordingly, the rubbing defect generated near the steps may be reduced when rubbing the alignment layer (not shown) formed on the pixel electrodes 191, and the non-uniformity of a cell gap caused by the height difference between a spacer disposed on the high portion and a spacer disposed on the low portion may be reduced by using ball spacers. Also, shorts between the storage electrode lines 131 and the pixel electrodes 191 may be reduced.

Next, a method for manufacturing the thin film transistor array panel will be described.

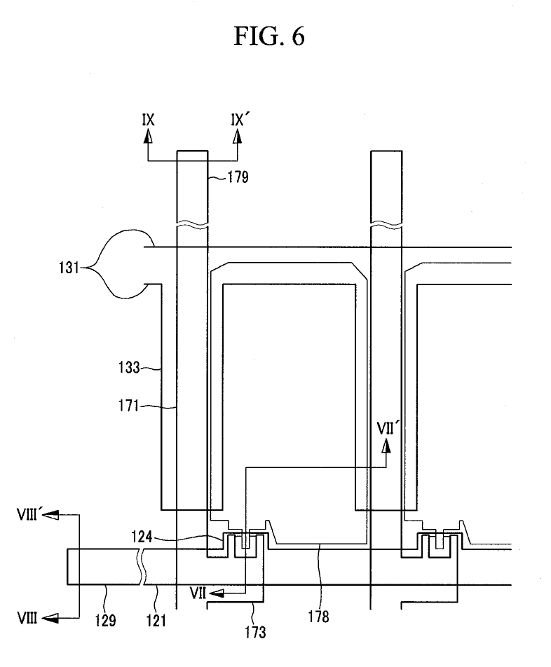

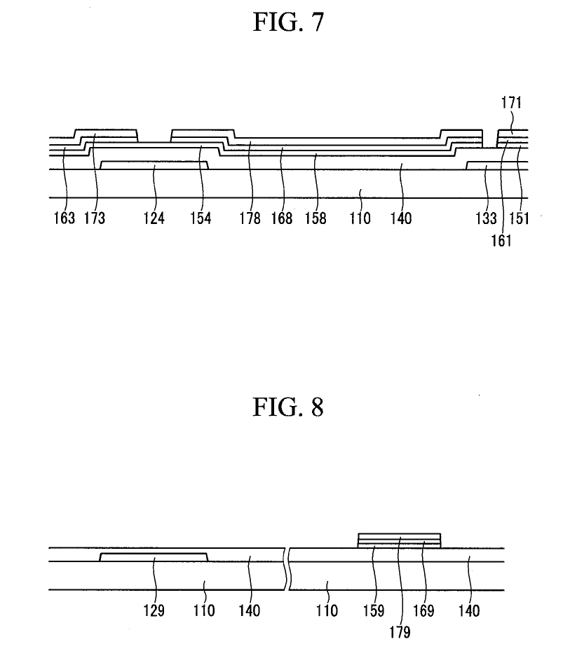

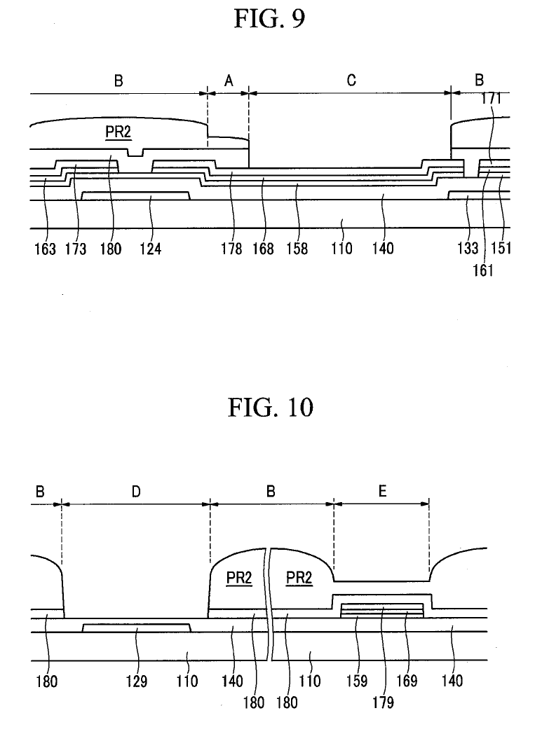

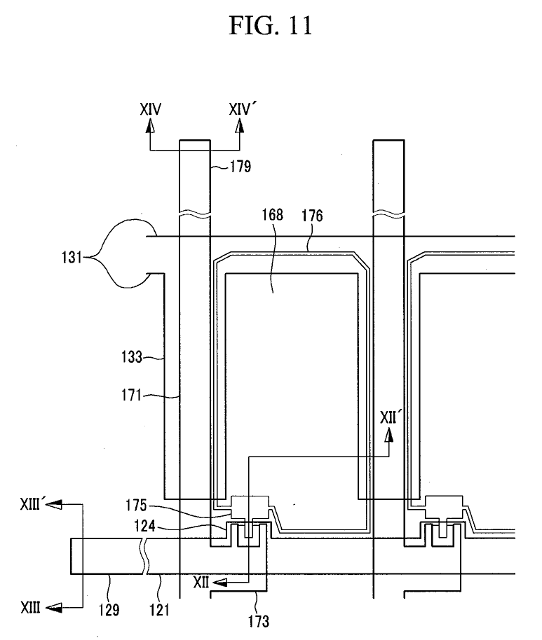

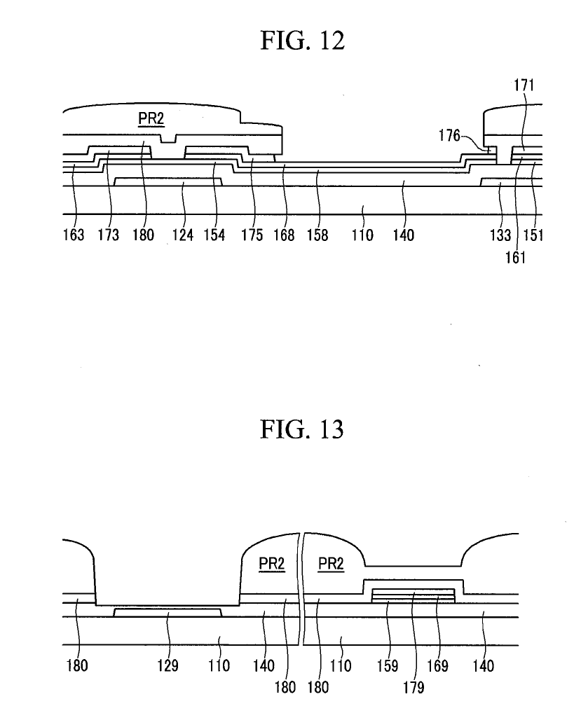

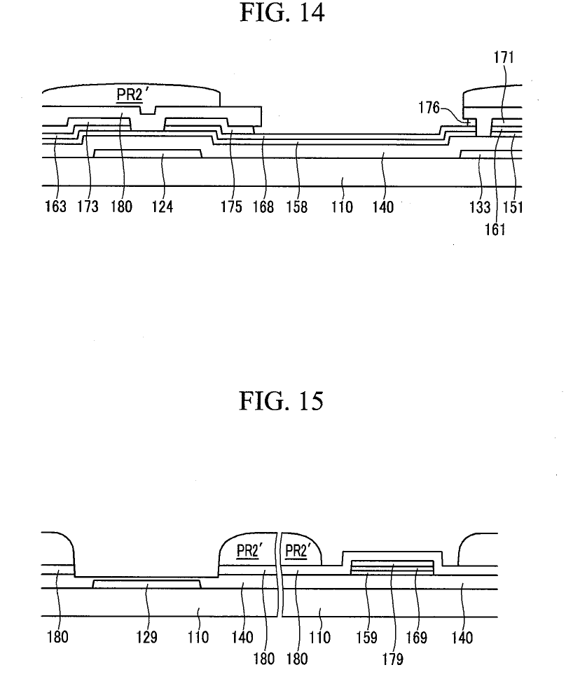

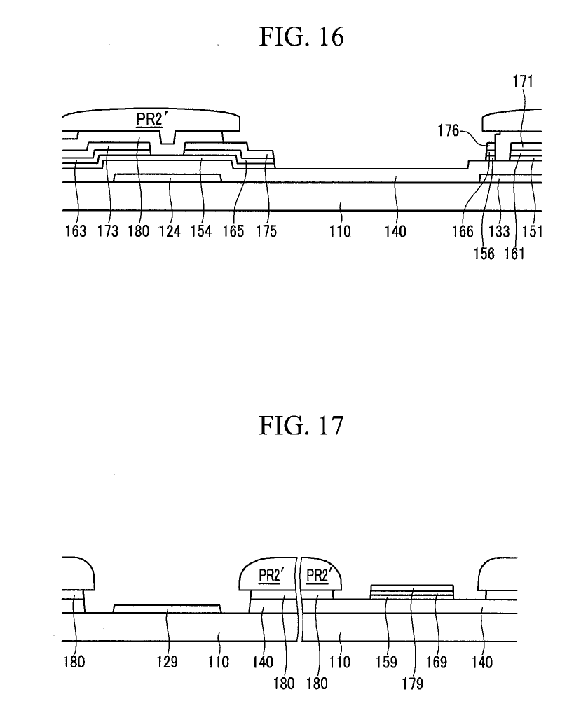

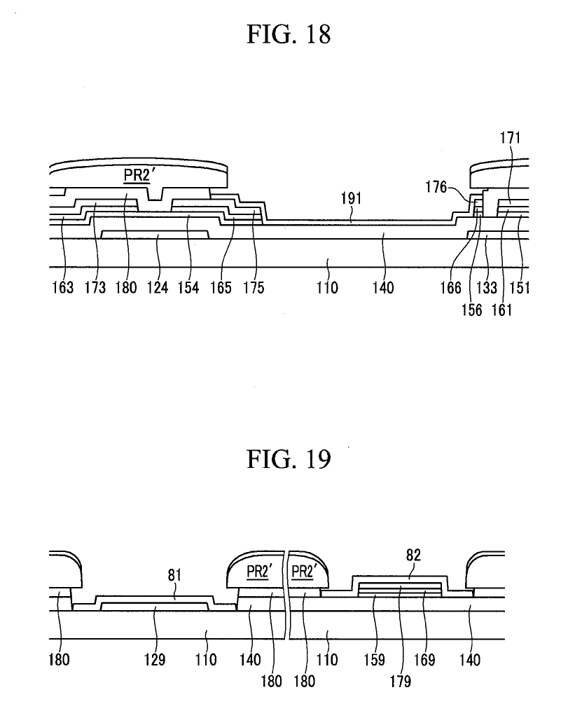

FIG. 6 and FIG. 11 are layout views showing intermediate steps of a manufacturing process of the thin film transistor array panel according to an exemplary embodiment of the present invention, FIG. 4, FIG. 7, FIG. 9, FIG. 12, FIG. 14, FIG. 16, and FIG. 18 are cross-sectional views showing intermediate steps of a manufacturing process of the thin film transistor array panel according to an exemplary embodiment of the present invention and taken along the line II-II′ of FIG. 1, and FIG. 5, FIG. 8, FIG. 10, FIG. 13, FIG. 15, FIG. 17, and FIG. 19 are cross-sectional views showing intermediate steps of a manufacturing process of the thin film transistor array panel according to an exemplary embodiment of the present invention and taken along the lines III-III′ and IV-IV′ of FIG. 1.

Referring to FIG. 4 and FIG. 5, a gate line 121 including a gate electrode 124 and an end portion 129, and a storage electrode line 131 including a storage electrode 133, are formed on an insulation substrate 110 by a photolithography process, and a gate insulating layer 140, an intrinsic semiconductor layer 150, an ohmic contact layer 160, and a data metal layer 170 are deposited on the gate line 121 and the storage electrode line 131. Next, a photosensitive film is coated on the data metal layer 170, and is exposed and developed by using a half-tone mask including a slit of a translucent region to form a photosensitive film pattern PR1 including a region A corresponding to a channel of a semiconductor and having a thin photosensitive film, a region B, corresponding to a data line 171 and a drain electrode 175 and enclosed by a edge metal layer 176 and having a thick photosensitive film, and a remaining region C, exposing the data metal layer 170.

Referring to FIG. 6 to FIG. 8, the data metal layer 170, the underlying ohmic contact layer 160, and the intrinsic semiconductor layer 150 are then etched by using the photosensitive film pattern PR1 as an etch mask to form a data line 171, a drain electrode 175, and a pixel area definition member 178, and an ohmic contact layer 161, 163, 165, 168, and 169 and an intrinsic semiconductor layer 151, 154, 158, and 159. The data metal layer 170 may be wet-etched, and the ohmic contact layer 160 and the intrinsic semiconductor layer 150 may be dry-etched. Next, the photosensitive film pattern PR1 is etched on the whole surface to reduce the thickness such that the data metal layer of the region A, where a channel will be formed is exposed, and the exposed data metal layer and the ohmic contact layer thereunder are removed such that the exposed data metal layer is divided into a source electrode 173 and a drain electrode 175, and the remaining photosensitive film pattern is removed by ashing. An ashing method using oxygen plasma may be used for the whole surface etching of the photosensitive film pattern PR1, wet etching may be used for the etching of the data metal layer 170, and dry etching may be used for the etching of the ohmic contact layer 160.

Referring to FIG. 9 and FIG. 10, a passivation layer 180 covering the data line 171, the drain electrode 175, the pixel area definition member 178, and the channel portion is deposited. Then, a photosensitive film is coated on the passivation layer 180, and is exposed and developed by using a half-tone mask having a slit or a translucent region to form a photosensitive film pattern PR2 including a portion C, corresponding to the pixel area definition member 178, a thin portion having the portion A, corresponding to a portion of the drain electrode 175 and a portion E, corresponding to the circumference of the end portion 179 of the data line 171, and a thick portion corresponding to the remaining portion B as well as the upper part of the data line 171 and the gate line 121, and exposing the passivation layer of the portion D, corresponding to the circumference of the end portion 129 of the gate line 121. The passivation layer 180 is then etched by using the photosensitive film pattern PR2 as an etch mask. Here, the portion of the gate insulating layer 140 near the end portion 129 of the gate line 121 may be etched. The etch method may comprise dry etching.

Next, referring to FIG. 11 to FIG. 13, the exposed pixel area definition member 178 formed by removing the passivation layer 180 is etched such that the ohmic contact layer 168 under the pixel area definition member 178 is exposed. The etch method may comprise wet etching. Here, if the photosensitive film pattern PR2 covers the portion of the edge of the pixel area definition member 178, the edge of the pixel area definition member 178 is not etched such that the edge metal layer 176 is formed.

Next, referring to FIG. 14 and FIG. 15, the photosensitive film pattern PR2 is etched with the whole surface to reduce the thickness such that the photosensitive film pattern PR2′ exposing the passivation layer 180 on the drain electrode 175 and near the end portion 179 of the data line is formed. An ashing method using an oxide plasma may be used for the whole surface etching of the photosensitive film pattern PR2.

Referring to FIG. 16 and FIG. 17, the passivation layer 180, the ohmic contact layer 168, and the intrinsic semiconductor layer 158 that are exposed are then etched by using the photosensitive film pattern PR2′ as an etch mask. Here, the gate insulating layer 140 that is exposed at the circumference of the end portion 129 of the gate line 121 is also etched. Here, the etching may progress in two steps. First, the first etching may progress under the condition that the etch selectivity for the ohmic contact layer 168 and the intrinsic semiconductor layer 158, and the passivation layer 180, is 1:1, and then the second etching may progress under the condition that the etch selectivity for the ohmic contact layer 168 and the intrinsic semiconductor layer 158, and the passivation layer 180, is 1:5. That is, the condition in which the semiconductors 168 and 158 and the passivation layer 180 are etched with almost the same speed may be used in the first etching, and the condition in which the passivation layer 180 is etched with a speed that is five times the speed of etching the semiconductors 168 and 158 may be used in the second etching. This is because the passivation layer 180 is over-etched to form the under-cut under the photosensitive film pattern PR2′. Thus, a portion of the thickness of the intrinsic semiconductor layer 158 is left in the first etching. Here, it is preferable that the thickness of the remaining intrinsic semiconductor layer 158 is in the range of 400-600 Å. Particularly, the thickness of the remaining intrinsic semiconductor layer 158 may be 500 Å. This is because the remaining intrinsic semiconductor layer 158 prevents the gate insulating layer 140 thereunder from being etched when forming the under-cut by over-etching the passivation layer 180 in the second etching. When the passivation layer 180 and the gate insulating layer 140 are made of the same material such as silicon nitride, substantial protection of the gate insulating layer 140 is required. On the other hand, the edge metal layer 176, the ohmic contact 166 and the intrinsic semiconductor 156 thereunder prevent the etching of the passivation layer 180 from progressing over them such that the region where a pixel electrode 191 will be formed may be defined.

Next, referring to FIG. 18 and FIG. 19, a conductive layer for a pixel electrode such as a transparent conductive material of ITO (indium tin oxide) or IZO (indium zinc oxide), or a conductive material having a reflection characteristic is deposited, and then the photosensitive film pattern PR2′ is removed such that the deposited conductive layer for the pixel electrode on the photosensitive film pattern PR2′ is removed. Accordingly, a pixel electrode 191 and contact assistants 81 and 82 are formed.

The thin film transistor array panel may be manufactured with three photolithography steps through the above-described progress. Also, the gate insulating layer 140 may remain under the pixel electrode 191, thereby reducing the failure rate of the thin film transistor array panel. While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A thin film transistor array panel comprising:
a substrate;
a gate line formed on the substrate and including a gate electrode;
a gate insulating layer formed on the gate line;
a semiconductor formed on the gate insulating layer and including a channel of a thin film transistor;
a data line formed on the semiconductor and including a source electrode;
a drain electrode formed on the semiconductor and facing the source electrode with respect to the channel of the thin film transistor;
a passivation layer covering the data line and the gate line, and having a first opening exposing the gate insulating layer of the pixel area enclosed by the data line and the gate line, and a portion of the drain electrode; and
a pixel electrode formed on the gate insulating layer in the first opening and connected to the drain electrode.

2. The thin film transistor array panel of claim 1, wherein
the plane shape of the pixel electrode is substantially the same as the plane shape of the first opening.

3. The thin film transistor array panel of claim 2, further comprising:
an edge member including a first layer made of the same material as the semiconductor and a second layer made of the same material as the data line, wherein the edge member is formed along the edge of the pixel electrode.

4. The thin film transistor array panel of claim 3, wherein
the edge of the pixel electrode covers one side and the upper surface of the edge member.

5. The thin film transistor array panel of claim 3, further comprising:
a storage electrode line formed of the same layer as the gate line, and including a plurality of storage electrodes extending along the data line.

6. The thin film transistor array panel of claim 5, wherein
the width of the storage electrode is wider than the width of the data line, and the data line is disposed inside the width of the storage electrode.

7. The thin film transistor array panel of claim 2, further comprising:
a storage electrode line formed of the same layer as the gate line, and including a plurality of storage electrodes extending along the data line.

8. The thin film transistor array panel of claim 7, wherein
the width of the storage electrode is wider than the width of the data line, and the data line is disposed inside the width of the storage electrode.

9. The thin film transistor array panel of claim 1, further comprising:
an edge member including a first layer made of the same material as the semiconductor and a second layer made of the same material as the data line, wherein the edge member is formed along the edge of the pixel electrode.

10. The thin film transistor array panel of claim 9, wherein
the edge of the pixel electrode covers one side and the upper surface of the edge member.

11. The thin film transistor array panel of claim 9, further comprising:
a storage electrode line formed of the same layer as the gate line, and including a plurality of storage electrodes extending along the data line.

12. The thin film transistor array panel of claim 11, wherein
the width of the storage electrode is wider than the width of the data line, and the data line is disposed inside the width of the storage electrode.

13. The thin film transistor array panel of claim 12, wherein
the passivation layer and the gate insulating layer include a second opening exposing an end portion of the gate line and the passivation layer has a third opening exposing an end portion of the data line, and
further comprising a first contact assistant covering the end portion of the gate line exposed through the second opening, and
a second contact assistant covering the end portion of the data line exposed through the third opening,
wherein the plane shape of the first contact assistant is substantially the same as the second opening, and the plane shape of the second contact assistant is substantially the same as the plane shape of the third opening.

14. The thin film transistor array panel of claim 13, wherein
the first contact assistant contacts the substrate near the end portion of the gate line, and the second contact assistant contacts the gate insulating layers near the end portion of the data line.

15. The thin film transistor array panel of claim 1, further comprising
a storage electrode line formed of the same layer as the gate line, and including a plurality of storage electrodes extending along the data line.

16. The thin film transistor array panel of claim 15, wherein
the width of the storage electrode is wider than the width of the data line, and the data line is disposed inside the width of the storage electrode.

17. The thin film transistor array panel of claim 1, wherein
the passivation layer and the gate insulating layer include a second opening exposing an end portion of the gate line and the passivation layer has a third opening exposing an end portion of the data line, and
wherein the thin film transistor array panel further comprises:
a first contact assistant covering the end portion of the gate line exposed through the second opening, and
a second contact assistant covering the end portion of the data line exposed through the third opening,
wherein the plane shape of the first contact assistant is substantially the same as the second opening, and the plane shape of the second contact assistant is substantially the same as the plane shape of the third opening.

18. The thin film transistor array panel of claim 17, wherein
the first contact assistant contacts the substrate near the end portion of the gate line, and the second contact assistant contacts the gate insulating layers near the end portion of the data line.

19. A method for manufacturing a thin film transistor array panel, comprising:
forming a gate line including a gate electrode;
forming a gate insulating layer on the gate line;
forming a semiconductor including a channel, a data line including a source electrode, a drain electrode, and a pixel area definition member on the gate insulating layer;
depositing a passivation layer on the data line, the pixel area definition member, and the channel of the semiconductor;
forming a first photosensitive film pattern including a first portion disposed at a position corresponding to the drain electrode and a second portion that is thicker than the first portion, and exposing the passivation layer of the position corresponding to the pixel area definition member on the passivation layer;
etching the exposed passivation layer by using the first photosensitive film pattern as an etch mask;
forming a second photosensitive film pattern by etching the whole surface of the first photosensitive film pattern to remove the first portion;
etching the pixel area definition member exposed by the etching of the passivation layer;
etching the passivation layer that is exposed by the removal of the first portion, and the semiconductor that is exposed by the removal of the pixel area definition member;
forming a conductor layer for a pixel electrode; and
removing the second photosensitive film pattern to form the pixel electrode.

20. The method of claim 19, wherein:
the first photosensitive film pattern exposes a portion of the passivation layer corresponding to the end portion of the gate line, and includes a third portion disposed at a position corresponding to the end portion of the data line and being thinner than the second portion;
the portion of the passivation layer corresponding to the end portion of the gate line is removed in the etching the exposed passivation layer by using the first photosensitive film pattern as an etch mask;
the third portion is removed in the forming a second photosensitive film pattern by etching the whole surface of the first photosensitive film pattern to remove the first portion,
a portion of the passivation layer which is exposed by the removal of the third portion is removed to expose the end portion of the data line in the etching the passivation layer that is exposed by the removal of the first portion, and the semiconductor that is exposed by the removal of the pixel area definition member.

21. The method of claim 20, wherein
a first contact assistant covering the end portion of the gate line and a second contact assistant covering the end portion of the data line are formed in the removing of the second photosensitive film pattern to form the pixel electrode.

22. The method of claim 21, wherein
the forming a semiconductor including a channel, a data line including a source electrode, a drain electrode, and a pixel area definition member on the gate insulating layer includes:
continuously depositing an amorphous silicon layer, a doped amorphous silicon layer, and a data metal layer on the gate insulating layer;
forming a third photosensitive film pattern including a fourth portion disposed at a position corresponding to the channel, and a fifth portion that is thicker than the fourth portion and is disposed at a position corresponding to the data line, the drain electrode, and the pixel area definition member on the data metal layer;
etching the data metal layer, the doped amorphous silicon layer, and the amorphous silicon layer by using the third photosensitive film pattern as a mask;
etching the whole surface of the third photosensitive film pattern to remove the fourth portion and form a fourth photosensitive film pattern; and
etching the data metal layer and the doped amorphous silicon layer by using the fourth photosensitive film pattern as a mask.

23. The method of claim 22, wherein
the etching the passivation layer that is exposed by the removal of the first portion, and the semiconductor that is exposed by the removal of the pixel area definition member includes:
a first etching executed under a condition in which an etch selectivity for the semiconductor and the passivation layer is 1:1; and
a second etching executed under a condition in which an etch selectivity for the semiconductor and the passivation layer is 1:5.

24. The method of claim 23, wherein
the semiconductor is left with a thickness of 400-600 Å in the first etching, and the passivation layer is over-etched to form an under-cut under the second photosensitive film pattern in the second etching.

25. The method of claim 19, wherein
a storage electrode line including a plurality of storage electrodes extending along the data line is formed in the forming of a gate line including a gate electrode.

26. The method of claim 19, wherein
the etching the passivation layer that is exposed by the removal of the first portion, and the semiconductor that is exposed by the removal of the pixel area definition member includes:
a first etching executed under a condition in which an etch selectivity for the semiconductor and the passivation layer is 1:1; and
a second etching executed under a condition in which an etch selectivity for the semiconductor and the passivation layer is 1:5.

27. The method of claim 26, wherein
the semiconductor is left with a thickness of 400-600 Å in the first etching, and the passivation layer is over-etched to form an under-cut under the second photosensitive film pattern in the second etching.

28. The method of claim 19, wherein
the forming a semiconductor including a channel, a data line including a source electrode, a drain electrode, and a pixel area definition member on the gate insulating layer includes:
continuously depositing an amorphous silicon layer, a doped amorphous silicon layer, and a data metal layer on the gate insulating layer;
forming a third photosensitive film pattern including a fourth portion disposed at a position corresponding to the channel, and a fifth portion that is thicker than the fourth portion and disposed at a position corresponding to the data line, the drain electrode, and the pixel area definition member on the data metal layer;
etching the data metal layer, the doped amorphous silicon layer, and the amorphous silicon layer by using the third photosensitive film pattern as a mask;
etching the whole surface of the third photosensitive film pattern to remove the fourth portion and form a fourth photosensitive film pattern; and
etching the data metal layer and the doped amorphous silicon layer by using the fourth photosensitive film pattern as a mask.
